(19) United States
(12) Patent Application Publication
(10) Pub. No.: US 2018/0033898 A1
(43) Pub. Date: Feb. 1, 2018

(54) SOLAR CELL AND METHOD OF MANUFACTURING SOLAR CELL

(71) Applicant: Panasonic Intellectual Property Management Co., Ltd., Osaka (JP)

(72) Inventors: Masato SHIGEMATSU, Osaka (JP); Yasufumi TSUNOMURA, Osaka (JP)

(21) Appl. No.: 15/716,361

(22) Filed: Sep. 26, 2017

Related U.S. Application Data
(63) Continuation of application No. PCT/JP2016/000940, filed on Feb. 23, 2016.

(30) Foreign Application Priority Data
Mar. 30, 2015 (JP) 2015-069718

(51) Int. Cl. H01L 31/0224; H01L 31/05; H01L 31/068

(52) U.S. Cl. CPC H01L 31/022425; H01L 31/0682; H01L 31/022466; H01L 31/05; H01L 31/0445

(57) ABSTRACT

A solar cell includes: a first semiconductor layer provided in a first area on a principal surface; an insulating layer provided on the first semiconductor layer in an insulating area adjacent to a second area; a second semiconductor layer provided to extend across the principal surface in the second area and the insulating layer in the insulating area; a transparent conductive layer provided on the first semiconductor layer and the second semiconductor layer; a first metal electrode provided in the first area; and a second metal electrode provided in the second area. The second metal electrode is formed to have an overhanging portion projecting to approach the first metal electrode with increasing distance from the principal surface and such that a gap from the first metal electrode is positioned in the insulating area. The transparent conductive layer is provided to avoid an isolation area aligned with the gap.

### RELATED APPLICATION

Priority is claimed to Japanese Patent Application No. 2015-069718, filed on Mar. 30, 2015, the entire content of which is incorporated herein by reference.

### BACKGROUND OF THE INVENTION

### 1. Field of the Invention

The present invention relates to a method of manufacturing a solar cell and particularly to a method of manufacturing a back surface junction type solar cell.

### 2. Description of the Related Art

Solar cells having high power generation efficiency include back surface junction type solar cells with an n-type semiconductor layer and a p-type semiconductor layer formed on a back surface thereof, which is opposite to a light-receiving surface on which light becomes incident. In back surface junction type solar cells, both an n-side electrode and a p-side electrode to retrieve generated power are provided on the back surface. The n-side electrode and the p-side electrode include a plating layer formed by plating.

### SUMMARY OF THE INVENTION

It is desired to provide more reliable solar cells.

In this background, a purpose of the present invention is to provide solar cells with improved reliability.

One embodiment of the present invention relates to a method of manufacturing a solar cell. The method includes: forming a first semiconductor layer of a first conductivity type in a first area on a principal surface of a semiconductor substrate having the first area and a second area adjacent to each other; forming an insulating layer on the first semiconductor layer in an insulating area that is part of the first area and adjacent to the second area; forming a second semiconductor layer of a second conductivity type to extend across the principal surface in the second area and the insulating layer in the insulating area; forming a transparent conductive layer on the first semiconductor layer and the second semiconductor layer; forming a seed layer on the transparent conductive layer; forming a plating layer to grow on the seed layer and on a plating resist provided on the seed layer in the insulating area; and removing the plating resist and removing a portion of the transparent conductive layer and the seed layer. The forming the plating layer includes forming a first plating layer on the first area and forming a second plating layer on the second area. The forming the second plating layer includes forming the second plating layer to project to approach the first plating layer with increasing distance from the principal surface and such that a gap is provided between the second plating layer and the first plating layer. The removing a portion of the transparent conductive layer and the seed layer includes irradiating a portion of the transparent conductive layer with laser or dry etching the transparent conductive layer, by using the gap as a mask.

Another embodiment of the present invention relates to a solar cell. The solar cell includes: a semiconductor substrate having a principal surface in which a first area and a second area adjacent to each other are provided; a first semiconductor layer of a first conductivity type provided in the first area on the principal surface; an insulating layer provided on the first semiconductor layer in an insulating area that is part of the first area and adjacent to the second area; a second semiconductor layer of a second conductivity type provided to extend across the principal surface in the second area and the insulating layer in the insulating area; a transparent conductive layer provided on the first semiconductor layer and the second semiconductor layer; a first metal electrode provided on the transparent conductive layer in the first area; and a second metal electrode provided on the transparent conductive layer in the second area. The second metal electrode is formed to have an overhanging portion projecting to approach the first metal electrode with increasing distance from the principal surface and such that a gap from the first metal electrode is positioned in the insulating area, and the transparent conductive layer is provided to avoid an isolation area in the insulating area aligned with the gap.

### BRIEF DESCRIPTION OF THE DRAWINGS

Embodiments will now be described by way of examples only, with reference to the accompanying drawings which are meant to be exemplary, not limiting, and wherein like elements are numbered alike in several Figures in which:

FIG. 1 is a plan view illustrating a solar cell according to an embodiment;

FIG. 2 is a cross-sectional view illustrating the structure of a solar cell;

FIG. 3 is a plan view illustrating a first area of the solar cell;

FIG. 4 is a plan view illustrating a second area of the solar cell;

FIG. 5 is a plan view illustrating an insulating area of the solar cell;

FIG. 6 is a cross-sectional view illustrating the structure of the solar cell;

FIG. 7 is a cross-sectional view illustrating the structure of the solar cell;

FIG. 8 is a cross-sectional view schematically illustrating a process of manufacturing the solar cell;

FIG. 9 is a cross-sectional view schematically illustrating a process of manufacturing the solar cell;

FIG. 10 is a cross-sectional view schematically illustrating a process of manufacturing the solar cell;

FIG. 11 is a cross-sectional view schematically illustrating a process of manufacturing the solar cell;

FIG. 12 is a cross-sectional view schematically illustrating a process of manufacturing the solar cell;

FIG. 13 is a cross-sectional view schematically illustrating a process of manufacturing the solar cell;

FIG. 14 is a cross-sectional view schematically illustrating a process of manufacturing the solar cell;

FIG. 15 is a cross-sectional view schematically illustrating a process of manufacturing the solar cell;

FIG. 16 is a cross-sectional view schematically illustrating a process of manufacturing the solar cell;

FIG. 17 is a cross-sectional view schematically illustrating a process of manufacturing the solar cell;

FIG. 18 is a cross-sectional view schematically illustrating a process of manufacturing the solar cell;

FIG. 19 is a cross-sectional view schematically illustrating a process of manufacturing the solar cell;

FIG. 20 is a cross-sectional view schematically illustrating a process of manufacturing the solar cell;

FIG. 21 is a cross sectional view illustrating the structure of a solar cell according to a comparative example;

FIG. 22 is a cross sectional view showing the structure of the solar cell on which a connection member is attached;

FIG. 23 is a cross sectional view illustrating the structure of a solar cell according to a variation; and

FIG. 24 is a cross sectional view illustrating the structure of a solar cell according to a variation.

### DETAILED DESCRIPTION

The invention will now be described by reference to the preferred embodiments. This does not intend to limit the scope of the present invention, but to exemplify the invention.

A brief description is now given before focusing on specific features of the present invention. An embodiment of the present invention relates to a method of manufacturing a solar cell. The method comprises: forming a first semiconductor layer of a first conductivity type in a first area on a principal surface of a semiconductor substrate having the first area and a second area adjacent to each other; forming an insulating layer on the first semiconductor layer in an insulating area that is part of the first area and adjacent to the second area; forming a second semiconductor layer of a second conductivity type to extend across the principal surface in the second area and the insulating layer in the insulating area; forming a transparent conductive layer on the first semiconductor layer and the second semiconductor layer; forming a seed layer on the transparent conductive layer; forming a plating layer to grow on the seed layer and on a plating resist provided on the seed layer in the insulating area; and removing the plating resist and removing a portion of the transparent conductive layer and the seed layer.

The forming the plating layer in the method includes forming a first plating layer on the first area and forming a second plating layer on the second area. The forming the second plating layer includes forming the second plating layer to project to approach the first plating layer with increasing distance from the principal surface and such that a gap is provided between the second plating layer and the first plating layer. The removing a portion of the transparent conductive layer and the seed layer includes irradiating a portion of the transparent conductive layer with laser or dry etching the transparent conductive layer, by using the gap as a mask.

According to the embodiment, the plating layer is formed on the transparent conductive layer covering the first semiconductor layer and the second semiconductor layer. Therefore, the plating layer is prevented from being directly in contact with the first semiconductor layer or the second semiconductor layer. This prevents the metal constituting the plating layer from being in contact with the first semiconductor layer or the second semiconductor layer and affecting the property of the solar cell accordingly. Since a space is provided between the plating layer overhanging outward with increasing distance from the principal surface and the transparent conductive layer, a distance is secured between the second semiconductor layer exposed by removing a portion of the transparent conductive layer and the plating layer This prevents the second semiconductor layer from being in direct contact with the plating layer more properly.

Hereinafter, an embodiment for carrying out the present invention will be described in detail with reference to the accompanying drawing. In the explanations of the figures, the same elements shall be denoted by the same reference numerals, and duplicative explanations will be omitted appropriately.

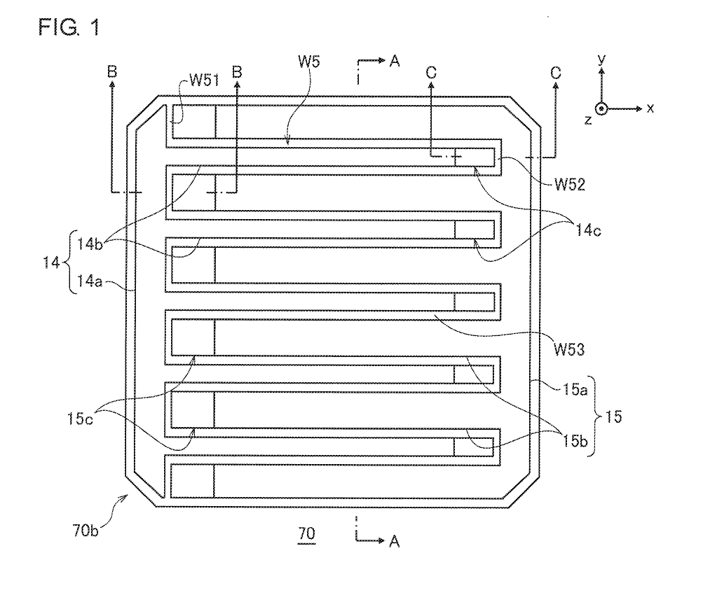

FIG. 1 is a plan view illustrating a solar cell 70 according to an embodiment and shows the structure of a back surface 70b of the solar cell 70. The solar cell 70 includes a first electrode 14 and a second electrode 15 provided on the back surface 70b. The first electrode 14 includes a first bus bar electrode 14a extending in the y direction and a plurality of first finger electrodes 14b extending in the x direction and is formed in a comb-tooth shape. Similarly, the second electrode 15 includes a second bus bar electrode 15a extending in the y direction and a plurality of second finger electrodes 15b extending in the x direction. The first electrode 14 and the second electrode 15 are formed such that the plurality of first finger electrodes 14b and the plurality of second finger electrodes 15b are engaged with each other and inserted into each another.

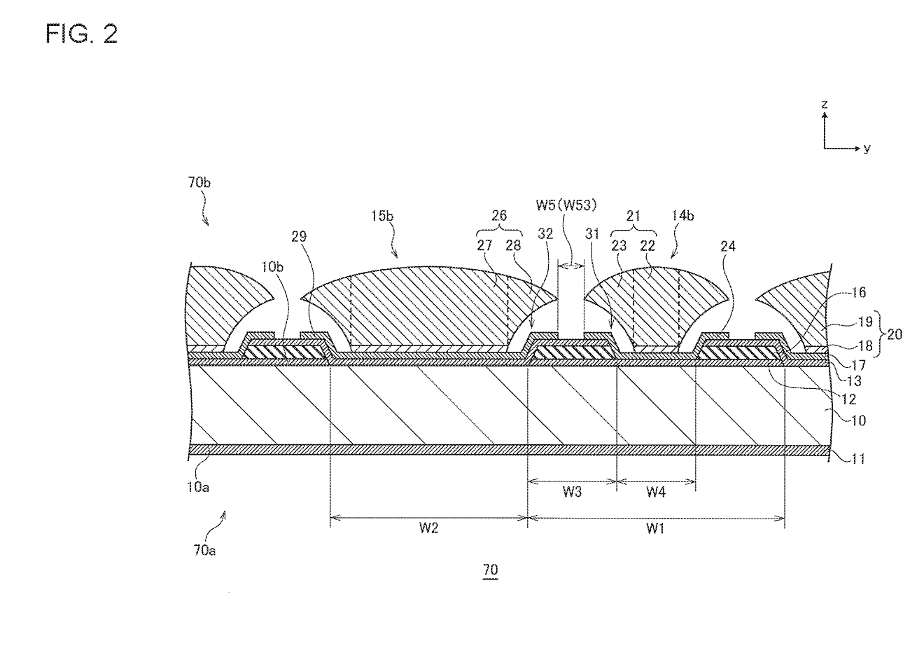

As described later with reference to FIG. 2 below, each of the first electrode 14 and the second electrode 15 is comprised of a transparent conductive layer 17 and a metal electrode layer 20 provided thereon. Stated otherwise, each of the first bus bar electrode 14a, the first finger electrode 14b, the second bus bar electrode 15a, and the second finger electrode 15b is built in a dual structure of the transparent conductive layer 17 and the metal electrode layer 20. A first finger end portion 14c in which the metal electrode layer 20 is not provided and the transparent conductive layer 17 is exposed is provided at the end of the first finger electrode 14b. Similarly, a second finger end portion 15c in which the metal electrode layer 20 is not provided and the transparent conductive layer 17 is exposed is provided at the end of the second finger electrode 15b.

An isolation area W5 (W51, W52, W53) is provided between the first electrode 14 and the second electrode 15. The isolation area W5 is an area in which the transparent conductive layer 17 and the metal electrode layer 20 forming the first electrode 14 and the second electrode 15 are removed. The isolation area W5 ensures insulation between the first electrode 14 and the second electrode 15. A first bus bar isolation area W51 is provided between the first bus bar electrode 14a and the second finger end portion 15c. A second bus bar isolation area W52 is provided between the second bus bar electrode 15a and the first finger end portion 14c. A finger isolation area W53 is provided between the first finger electrode 14b and the second finger electrode 15b.

FIG. 2 shows the structure of the solar cell 70 according to the embodiment and shows an A-A cross section of FIG. 1. The solar cell 70 includes a semiconductor substrate 10, a light receiving surface protection layer 11, a first semiconductor layer 12, a second semiconductor layer 13, an insulating layer 16, a transparent conductive layer 17, and a metal electrode layer 20. The metal electrode layer 20 includes a seed layer 18 and a plating layer 19. As described above, the transparent conductive layer 17 and the metal electrode layer 20 form the first electrode 14 or the second electrode 15. The figure shows the first finger electrode 14b and the second finger electrode 15b to illustrate the first electrode 14 and the second electrode 15. The solar cell 70 is a back surface junction type photovoltaic device in which the first semiconductor layer 12 and the second semiconductor layer 13 having different conductivity types are provided on the back surface 70b and the electrodes are not provided on the light receiving surface 70a.

The semiconductor substrate 10 has a first principle surface 10a provided on the side of the light-receiving surface 70a and a second principle surface 10b provided on the side of the back surface 70b. The semiconductor substrate 10 absorbs light that becomes incident on the first principle surface 10a and generates electrons and positive holes as carriers. The semiconductor substrate 10 is formed of a crystalline semiconductor material of an n-type or p-type conductivity. The semiconductor substrate 10 in the embodiment is an n-type monocrystalline silicon substrate.

The light-receiving surface 70a means a principal surface on which light (sunlight) mainly becomes incident in the solar cell 70 and, specifically, means a surface on which the major portion of light entering the solar cell 70 becomes incident. On the other hand, the back surface 70b means the other principal surface opposite to the light-receiving surface 70a.

The first semiconductor layer 12 and the second semiconductor layer 13 are formed on the second principal surface 10b of the semiconductor substrate 10. Each of the first semiconductor layer 12 and the second semiconductor layer 13 is formed in a comb-tooth shape corresponding to the first electrode 14 and the second electrode 15, respectively. The first semiconductor layer 12 and the second semiconductor layer 13 are formed so as to be inserted into each other. Therefore, a first area W1 in which the first semiconductor layer 12 is provided and a second area W2 in which the second semiconductor layer 13 is provided are alternately arranged in the y direction. Further, the first semiconductor layer 12 and the second semiconductor layer 13 adjacent in the y direction are provided in contact with each other.

The first semiconductor layer 12 is a semiconductor layer having a first conductivity type and is formed of an amorphous semiconductor layer having an n-type conductivity like the semiconductor substrate 10. The first semiconductor layer 12 is built in a dual structure including, for example, a substantially intrinsic i-type amorphous semiconductor layer formed on the second principal surface 10b and an n-type amorphous semiconductor layer formed on the i-type amorphous semiconductor layer. In this embodiment, it is assumed that an “amorphous semiconductor” may include a microcrystalline semiconductor. A microcrystalline semiconductor is a semiconductor where semiconductor crystals are deposited in an amorphous semiconductor.

The i-type amorphous semiconductor layer is formed of an i-type amorphous silicon containing hydrogen (H) and has a thickness of, for example, about 2 nm to 25 nm. The n-type amorphous semiconductor layer is formed of an n-type amorphous silicon containing hydrogen doped with an n-type dopant and has a thickness of, for example, about 2 nm to 50 nm. A method of forming the layers of the first semiconductor layer 12 is not particularly limited. For example, the layers can be formed by a chemical vapor deposition (CVD) method such as a plasma CVD method.

The insulating layer 16 is formed on the first semiconductor layer 12. The insulating layer 16 is not provided in a contact area W4 corresponding to the central portion of the first area W1 in the y direction and is provided in an insulating area W3 corresponding to the ends outside the contact area W4. In this way, a first step 31 is provided at the boundary between the insulating area W3 and the contact area W4. The insulating area W3 in which the insulating layer 16 is formed is, for example, about ⅓ the first area W1. Further, the contact area W4 in which the insulating layer 16 is not provided is, for example, about ⅓ the first area W1.

The insulating layer is formed of, for example, silicon oxide (SiO₂), silicon nitride (SiN), silicon oxynitride (SiON), or the like. The insulating layer 16 is desirably formed of silicon nitride.

The second semiconductor layer 13 is formed on the second area W2 of the second principal surface 10b in which the first semiconductor layer 12 is not provided and in the insulating area W3 in which the insulating layer 16 is provided. For this reason, the ends of the second semiconductor layer 13 are provided to overlap the first semiconductor layer 12 in the height direction (z direction). In this way, a second step 32 is provided at the boundary between the first area W1 and the second area W2. In this embodiment, the second semiconductor layer 13 in the isolation area W5 remains unremoved but the second semiconductor layer 13 in the isolation area W5 may be removed in a variation.

The second semiconductor layer 13 is a semiconductor layer having a second conductivity type and is formed of an amorphous semiconductor layer having a p-type conductivity different from the semiconductor substrate 10. The second semiconductor layer 13 is built in a dual structure including, for example, a substantially intrinsic i-type amorphous semiconductor layer formed on the second principal surface 10b and an p-type amorphous semiconductor layer formed on the i-type amorphous semiconductor layer.

The i-type amorphous semiconductor layer is formed of an i-type amorphous silicon containing hydrogen (H) and has a thickness of, for example, about 2 nm to 25 nm. The p-type amorphous semiconductor layer is formed of an n-type amorphous silicon containing hydrogen doped with a p-type dopant and has a thickness of, for example, about 2 nm to 50 nm. A method of forming the layers of the second semiconductor layer 13 is not particularly limited. For example, the layers may be formed by a chemical vapor deposition (CVD) method such as a plasma CVD method.

The first electrode 14, which collects electrons, is formed on the first semiconductor layer 12. The second electrode 15, which collects holes, is formed on the second semiconductor layer 13. The isolation area W5 is formed between the first electrode 14 and the second electrode 15 so that the electrodes are electrically insulated from each other. As described above, the first electrode 14 and the second electrode 15 is each formed of a stack of the transparent conductive layer 17 and the metal electrode layer 20.

The transparent conductive layer 17 is formed of, for example, a transparent conductive oxide (TCO) such as a tin oxide (SnO₂), a zinc oxide (ZnO), an indium tin oxide (ITO), or the like. The transparent conductive layer 17 according to this embodiment is formed of an indium tin oxide and has a thickness of, for example, about 50 nm to 100 nm. The transparent conductive layer 17 can be formed by a thin film formation method such as sputtering and chemical vapor deposition (CVD).

The transparent conductive layer 17 is provided to avoid the isolation area W5 positioned at the center of the insulating area W3. In this way, the transparent conductive layer 17 is separated into a first transparent conductive layer 24 in contact with the first semiconductor layer 12 in the contact area W4 and a second transparent conductive layer 29 in contact with the second semiconductor layer 13 in the second area W2.

The metal electrode layer 20 is formed of a metal material such as copper (Cu), tin (Sn), gold (Au), silver (Ag), and nickel (Ni), titanium (Ti). The metal electrode layer 20 according to the embodiment is formed of copper and is comprised of two layers including the seed layer 18 and the plating layer 19. The seed layer 18 is formed on the transparent conductive layer 17 by a thin film formation method such as sputtering and chemical vapor deposition (CVD). The plating layer 19 is formed on the seed layer 18 by plating. The seed layer 18 has a thickness of, for example, about 50 nm to 1000 nm, and the plating layer 19 has a thickness of about 10 μm to 50 μm. A protective plating layer formed of, for example, tin may be further provided on the surface of the plating layer 19.

Like the transparent conductive layer 17, the metal electrode layer 20 is provided to avoid the isolation area W5. In this way, the metal electrode layer 20 is separated into a first metal electrode 21 provided on the first transparent conductive layer 24 and a second metal electrode 26 provided on the second transparent conductive layer 29.

The first metal electrode 21 includes a first base portion 22 provided in the contact area W4 and a first overhanging portion 23 that projects in the y direction to approach the second metal electrode 26 with increasing distance from the second principal surface 10b. The first base portion 22 is provided inside the contact area W4 and is provided to avoid a space above the first step 31 positioned at the boundary between the insulating area W3 and the contact area W4. The first overhanging portion 23 has a shape projecting from the contact area W4 toward the insulating area W3 and is provided at a distance from the first transparent conductive layer 24. Therefore, the first overhanging portion 23 is formed to overlap the first step 31 and is formed such that a space is provided between the first overhanging portion 23 and the first step 31.

The second metal electrode 26 includes a second base portion 27 provided in the second area W2 and a second overhanging portion 28 that projects in the y direction to approach the first metal electrode 21 with increasing distance from the second principal surface 10b. The second base portion 27 is provided inside the second area W2 and is provided to avoid a space above the second step 32 positioned at the boundary between the first area W1 and the second area W2. The second overhanging portion 28 has a shape projecting from the second area W2 toward the insulating area W3 and is provided at a distance from the second transparent conductive layer 29. Therefore, the second overhanging portion 28 is formed to overlap the second step 32 and is formed such that a space is provided between the second overhanging portion 28 and the second step 32.

A light receiving surface protection layer 11 is provided on the first principal surface 10a of the semiconductor substrate 10. The light receiving surface protection layer 11 is formed of, for example, silicon, silicon oxide, silicon nitride, silicon oxynitride, or the like. The light receiving surface protection layer 11 has a function of a passivation layer for the first principal surface 10a or a function of an antireflection film or a protection film.

The light receiving surface protection layer 11 according to the embodiment has a structure in which an i-type amorphous silicon layer and an insulating layer of silicon oxide or silicon nitride is stacked in sequence on the first principal surface 10a. The light receiving surface protection layer 11 may have a structure in which an n-type amorphous silicon layer is provided between an i-type amorphous silicon layer and an insulating layer. The i-type amorphous layer and the n-type amorphous layer has a thickness of, for example, about 2 nm to 50 nm. The insulating layer of silicon oxide, silicon nitride, or silicon oxynitride has a thickness of, for example, about 50 nm to 200 nm.

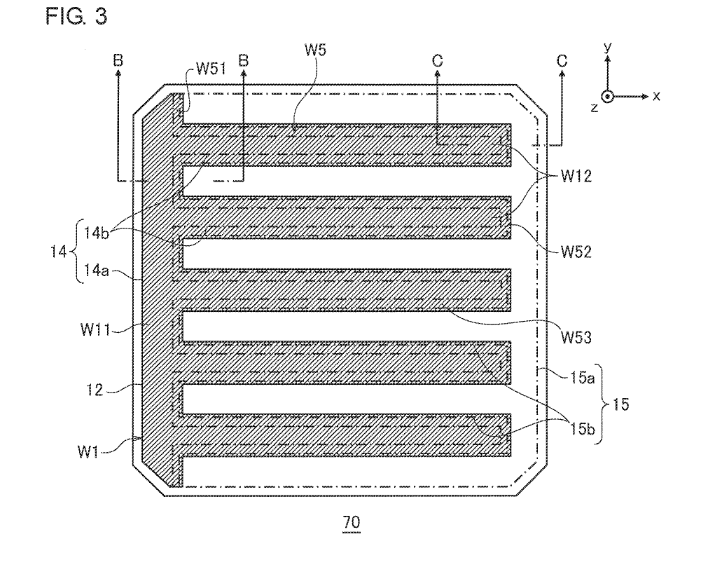

A description will now be given of a planar arrangement of the first area W1 in which the first semiconductor layer 12, the second semiconductor layer 13, and the insulating layer 16 are provided, the second area W2, and the insulating area W3 with reference to FIGS. 3 to 5.

FIG. 3 is a top plan showing the first area W1 of the solar cell 70 and shows the first semiconductor layer 12 provided in the first area W1 in diagonal lines. In this figure, the positions of the first electrode 14 and the second electrode 15 are indicated by dashed lines. The first area W1 includes a first bus bar area W11 corresponding to the first bus bar electrode 14a and a plurality of first finger areas W12 corresponding to the plurality of first finger electrodes 14b.

The first area W1 is provided to correspond to the area in which the first electrode 14 is provided and provided to be more extensive than the range in which the first electrode 14 is provided. More specifically, the range of the first area W1 is set so as to extend beyond the isolation area W5 (W51, W52, W53) between the first electrode 14 and the second electrode 15 and partially overlap the range in which the second electrode 15 is provided.

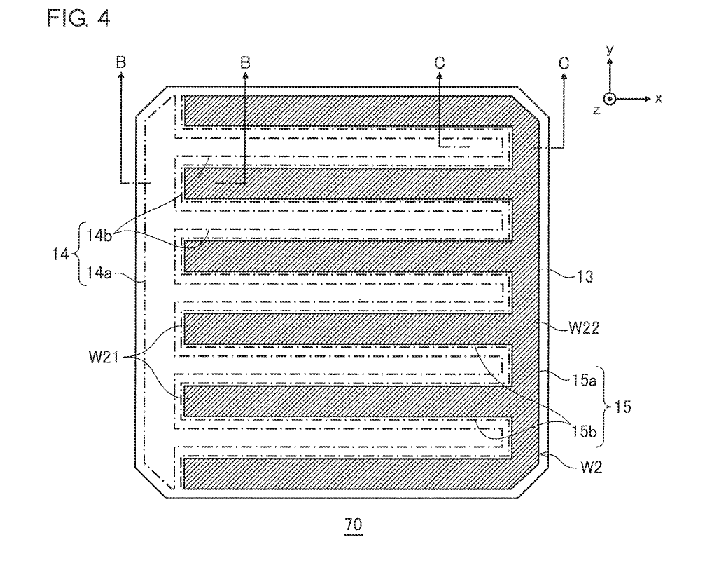

FIG. 4 is a plan view showing the second area W2 of the solar cell 70 and shows the second semiconductor layer 13 provided in the second area W2 in diagonal lines. The second area W2 includes a second bus bar area W22 corresponding to the second bus bar electrode 15a and a plurality of second finger areas W21 corresponding to the plurality of second finger electrodes 15b. The second area W2 is provided to correspond to the area in which the second electrode 15 is provided and provided to be narrower than the range in which the second electrode 15 is provided. More specifically, the range of the second area W2 is set so as to be slightly inside the range in which the second electrode 15 is provided.

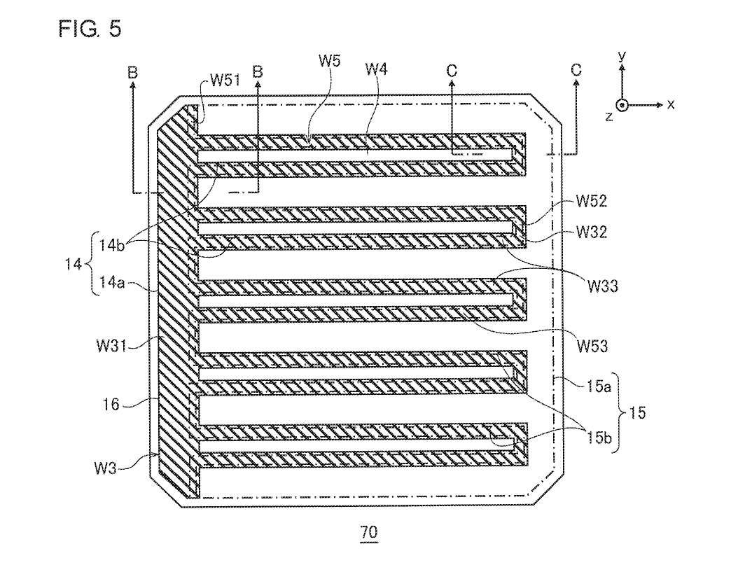

FIG. 5 is a plan view showing the insulating area W3 of the solar cell 70 and shows the insulating layer 16 provided in the insulating area W3 in diagonal lines. The insulating area W3 is provided in an area corresponding to the isolation area W5 and provided to be more extensive than the range in which the isolation area W5 is provided.

The insulating area W3 includes a first bus bar insulating area W31 corresponding to the first bus bar isolation area W51, a second bus bar insulating area W32 corresponding to the second bus bar isolation area W52, and a finger insulating area W33 corresponding to the finger isolation area W53. The insulating area W3 is provided to avoid the contact area W4. Further, the first bus bar insulating area W31 extends in the x direction as far as the area in which the first bus bar electrode 14a is provided. Of the insulating layer 16 provided in the insulating area W3, the insulating layer 16 in the area overlapping the seed layer 18 may be removed.

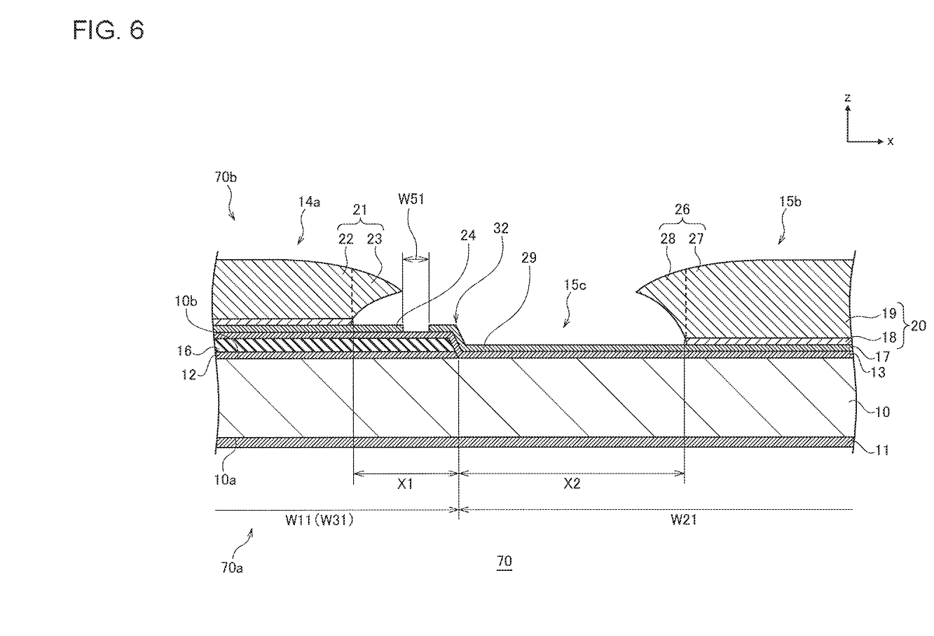

A description will now be given of the structure of the first finger end portion 14c and the second finger end portion 15c. FIG. 6 shows the structure of the solar cell 70 according to the embodiment and shows a B-B cross section of FIG. 1. The figure shows the structure of the second finger end portion 15c positioned between the first bus bar electrode 14a and the second finger electrode 15b.

The first bus bar electrode 14a is provided in the first bus bar area W1 and, more particularly, in the first bus bar insulating area W31 in which the insulating layer 16 is provided. The first base portion 22 of the first bus bar electrode 14a is provided at a position at which the length from the boundary between the first bus bar area W1, where the second step 32 is provided, and the second finger area W21 in the x direction is X1. For example, the length of X1 is about 0.1 mm to 0.3 mm. The first overhanging portion 23 of the first bus bar electrode 14a has a shape projecting toward the second finger electrode 15b in the x direction with increasing distance from the second principal surface 10b.

The second finger electrode 15b is provided in the second finger area W21. The second base portion 27 of the second finger electrode 15b is provided at a position at which the length in the x direction from the boundary between the first bus bar area W11 and the second finger area W21, where the second step 32 is provided, is X2, the length X2 being defined to be larger than the length X1. For example, the length of X2 is about 0.5 mm to 2 mm. The second overhanging portion 28 of the second finger electrode 15b has a shape projecting toward the first bus bar electrode 14a in the x direction with increasing distance from the second principal surface 10b.

The first bus bar isolation area W51 that isolates the first bus bar electrode 14a and the second finger electrode 15b is provided in the first bus bar area W11. More specifically, the first bus bar isolation area W51 is provided in the neighborhood of the first overhanging portion 23 of the first bus bar electrode 14a and at a distance from the second overhanging portion 28 of the second finger electrode 15b. In this way, a portion in which the second metal electrode 26 is not provided and the second transparent conductive layer 29 is exposed is formed in the second finger end portion 15c.

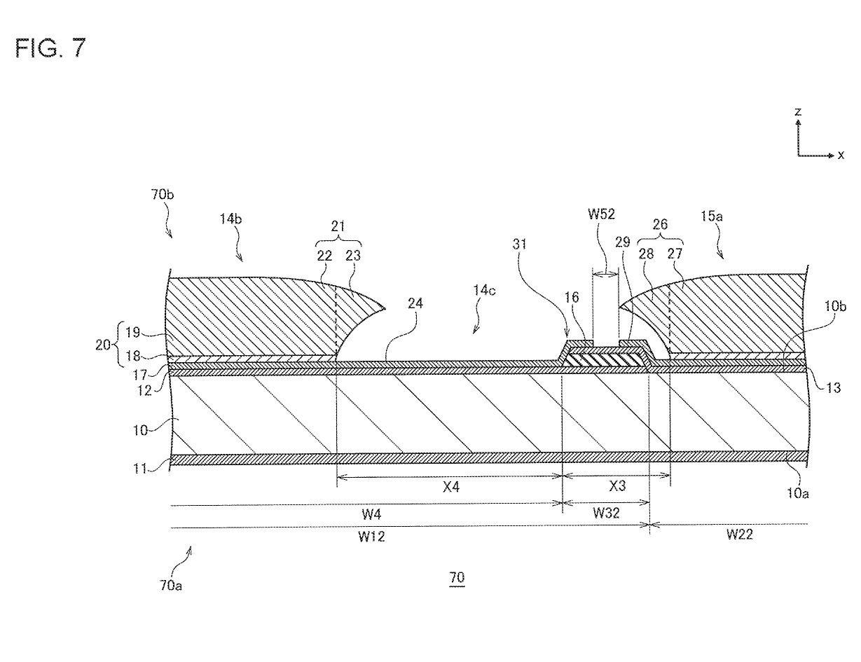

FIG. 7 shows the structure of the solar cell 70 according to the embodiment and shows a C-C cross section of FIG. 1. The figure shows the structure of the first finger end portion 14c positioned between the first finger electrode 14b and the second bus bar electrode 15a.

The second bus bar electrode 15a is provided in the second bus bar area W22. The second base portion 27 of the second finger electrode 15a is provided at a position at which the length from the boundary between the contact W4 and the second bus bar insulating area W32, where the first step 31 is provided, is X3. The length of X3 is, for example, about 0.1 mm to 0.3 mm. The second overhanging portion 28 of the second finger electrode 15a has a shape projecting toward the first finger electrode 14b in the x direction with increasing distance from the second principal surface 10b.

The first finger electrode 14b is provided in the contact area W4 in the first finger area W12 in which the insulating layer 16 is not provided. The first base portion 22 of the finger electrode 14b is provided at a position at which the length from the boundary between the contact area W4 and the second bus bar insulating area W32, where the first step 31 is provided, is X4, the length X4 being defined to be larger than the length X3. The length of X4 is, for example, about 0.5 mm to 2 mm. The first overhanging portion 23 of the first finger electrode 14b has a shape projecting toward the second bus bar electrode 15a in the x direction with increasing distance from the second principal surface 10b.

The second bus bar isolation area W52 that isolates the first finger electrode 14b and the second bus bar electrode 15a is provided in the second bus bar insulating area W32. Therefore, the second bus bar isolation area W52 is provided in the neighborhood of the second overhanging portion 28 of the second bus bar electrode 15a and at a distance from the first overhanging portion 23 of the first finger electrode 14b. In this way, a portion in which the first metal electrode 21 is not provided and the first transparent conductive layer 24 is exposed is formed in the first finger end portion 14c.

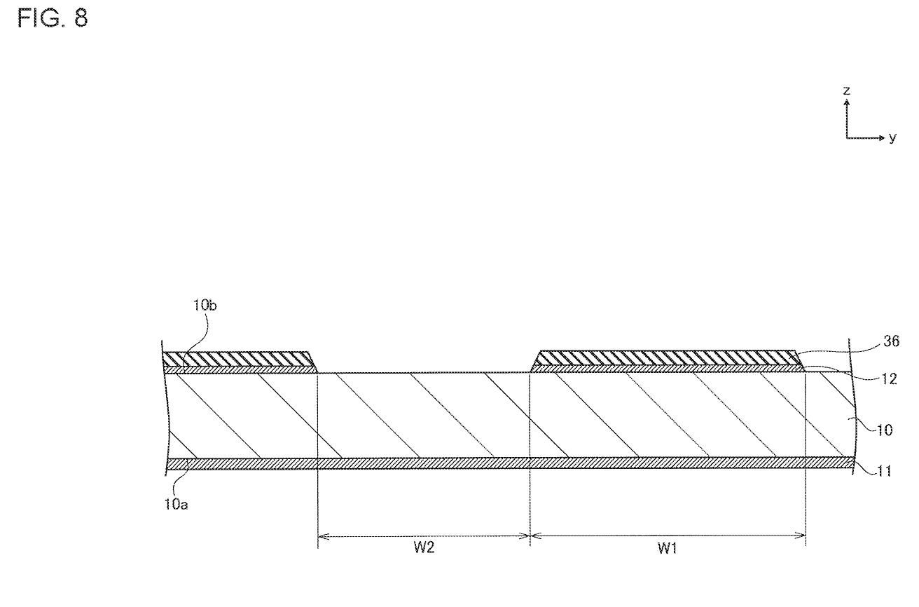

A description will now be given of a method of manufacturing the solar cell 70 with reference to FIGS. 8 to 20.

First, as shown in FIG. 8, the light receiving surface protection layer 11 is formed on the first principal surface 10a of the semiconductor substrate 10. Further, the first semiconductor layer 12 and the insulating layer 36 are formed in the first area W1 on the second principal surface 10b of the semiconductor substrate 10. In this embodiment, the light receiving surface protection layer 11 is formed before or after the step of forming the first semiconductor layer 12 and the insulating layer 36 by way of example. However, the step of forming the light receiving surface protection layer 11 is not limited to this example.

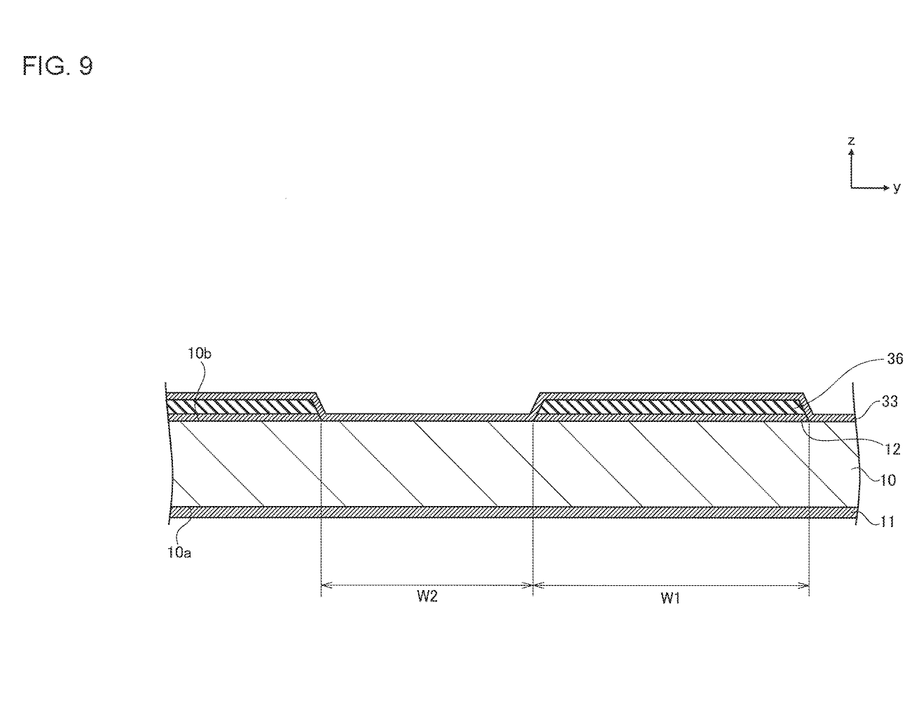

Subsequently, as shown in FIG. 9, the second semiconductor layer 33 is formed on the second principal surface 10b in the second area W2 and the first insulating layer 36 in the first area W1. The method of forming the light receiving surface protection layer 11, the first semiconductor layer 12, the second semiconductor layer 33, and the insulating layer 36 is not particularly limited. For example, the layers can be formed by a thin film formation method such as sputtering and chemical vapor deposition (CVD).

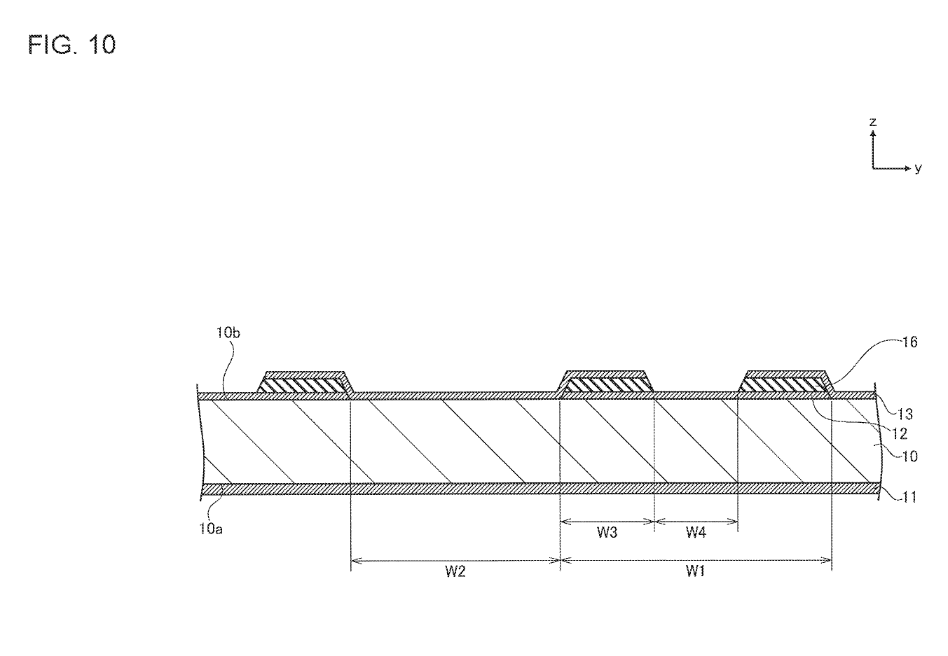

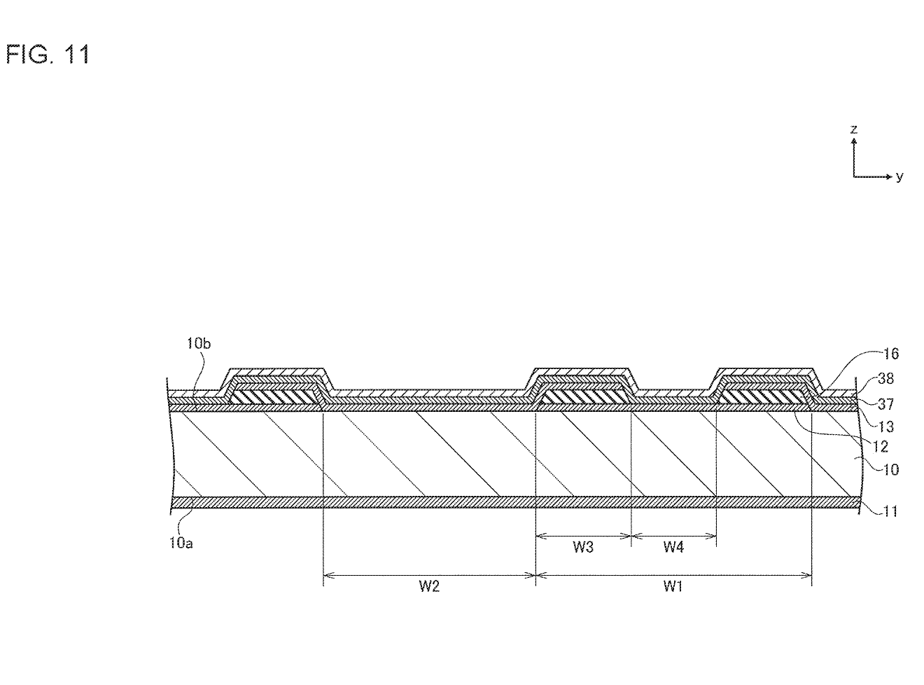

Subsequently, as shown in FIG. 10, the second semiconductor layer 33 and the insulating layer 36 provided in the contact area W4 corresponding to the central portion of the first area W1 are removed. In this way, the insulating layer 16 that remains in the insulating area W3 is formed from the insulating layer 36. The second semiconductor layer 13 that remains in the second area W2 and the insulating area W3 is formed from the second semiconductor layer 33. Subsequently, as shown in FIG. 11, the transparent conductive layer 37 is formed on the first semiconductor layer 12 and the second semiconductor layer 13, and the seed layer 38 is formed on the transparent conductive layer 37.

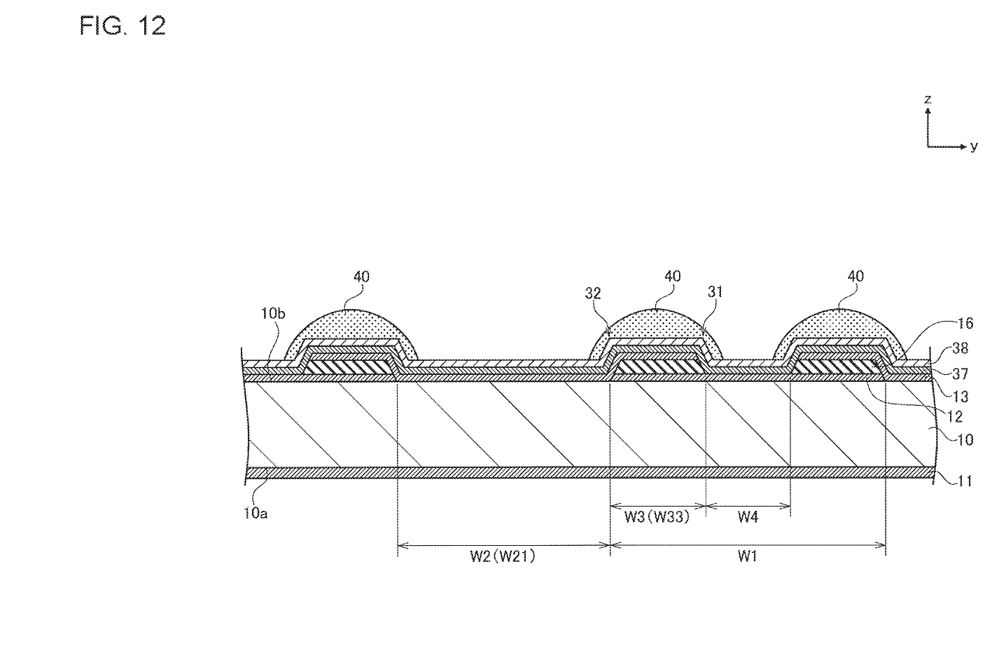

Subsequently, as shown in FIG. 12, a plating resist 40 is formed on the seed layer 38. As shown in FIG. 12, the plating resist 40 is provided at a position corresponding to the insulating area W3 and is provided to extend across a portion of the second area W2 (second finger area W21) and the contact area W4 adjacent to the insulating area W3 (finger insulating area W33). Therefore, the plating resist 40 is provided to cover the first step 31 positioned at the boundary between the insulating area W3 and the contact area W4 and cover the second step 32 positioned at the boundary between the first area W1 and the second area W2.

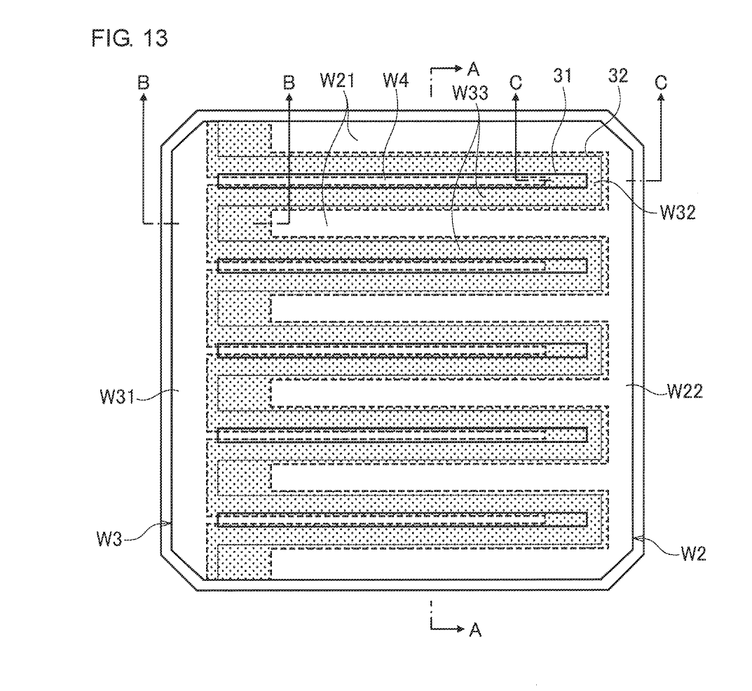

FIG. 13 is a plan view showing the arrangement of the plating resist 40. In this figure, the boundaries of the second area W2, the insulating area W3, and the contact area W4 are indicated by solid lines and the range in which the plating resist 40 is provided is indicated by broken lines. Further, the first step 31 positioned at the boundary between the insulating area W3 and the contact area W4 is indicated by solid lines and the second step 32 positioned at the boundary between the second area W2 and the insulating area W3 is indicated by fine solid lines. The A-A cross section of FIG. 13 corresponds to FIG. 12.

The plating resist 40 is provided to cover the entirety of the second bus bar insulating area W32 and the finger insulating area W33 in the insulating area W3. Further, the plating resist 40 is provided to cover the second bus bar insulating area W32, and the first step 31 and the second step 32 adjacent to the finger insulating area W3. Further, the plating resist 40 is provided in a portion of the first bus bar insulating area W31 adjacent to the second finger area W21 or the finger insulating area W33. In other words, the plating resist 40 is provided to avoid a portion of the first bus bar insulating area W31 adjacent to the contact area W4. Further, the plating resist 40 is provided at the end of the second finger area W21 adjacent to the first bus bar insulating area W31 and in a portion of the contact area W4 adjacent to the second bus bar area W22.

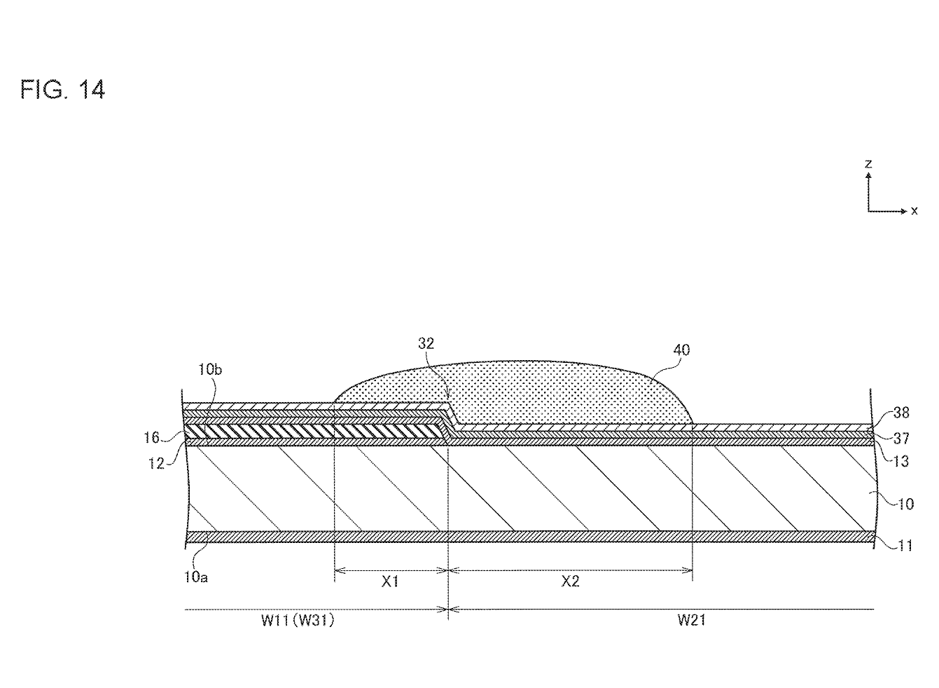

FIG. 14 is a cross sectional view showing the arrangement of the plating resist 40 and corresponds to the B-B cross section of FIG. 13. The plating resist 40 is provided to extend in the x direction so as to cover the second step 32 positioned at the boundary between the first bus bar area W1 (first bus bar insulating area W31) and the second finger area W21. Further, the plating resist 40 is provided such that the length X2 thereof extending from the boundary of the second step 32 toward the second finger area W21 in the x direction is larger than the length X1 thereof extending from the boundary of the second step 32 toward the first bus bar area W1 in the x direction.

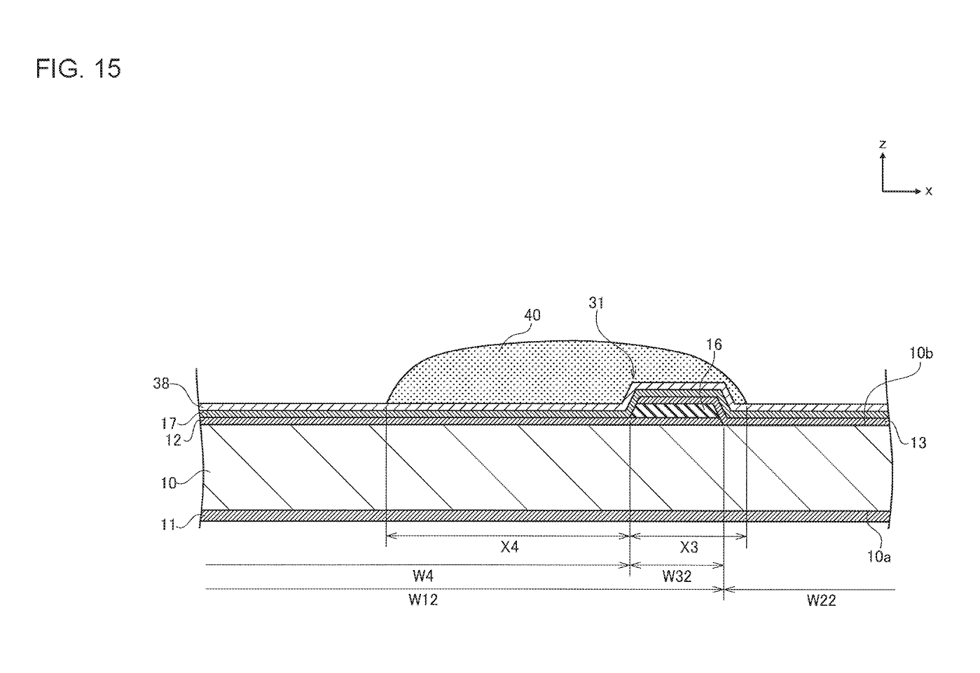

FIG. 15 is a cross sectional view showing the arrangement of the plating resist 40 and corresponds to the C-C cross section of FIG. 13. The plating resist 40 is provided to extend in the x direction so as to cover the first step 31 positioned at the boundary between the second bus bar insulating area W32 and the contact area W4. Further, the plating resist 40 is provided such that the length X4 thereof extending from the boundary of the first step 31 toward the contact area W4 in the x direction is larger than the length X3 thereof extending from the boundary of the first step 31 toward the second bus bar insulating area W32 in the x direction.

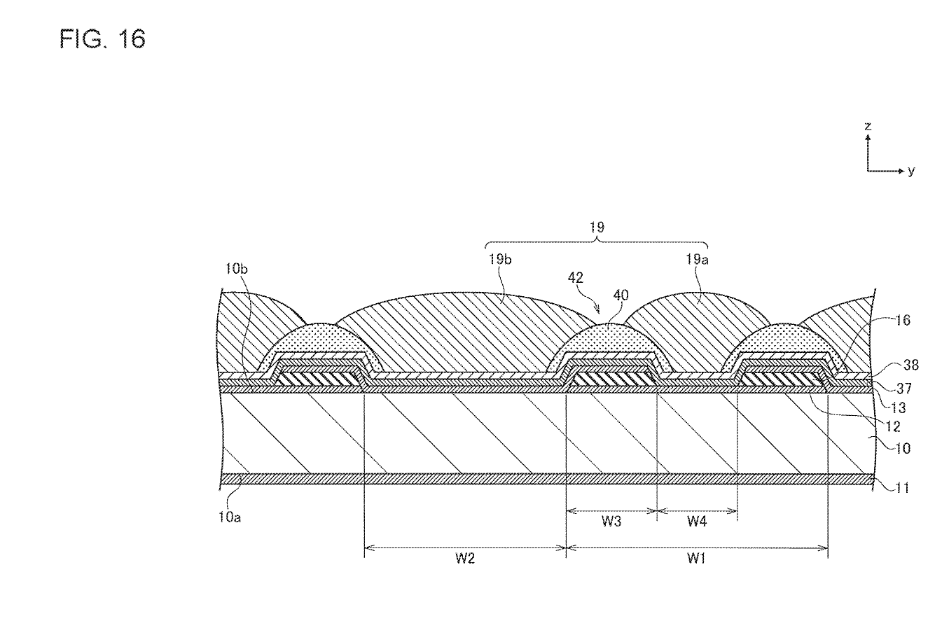

Subsequently, the plating layer 19 is formed on the seed layer 38 as shown in FIG. 16. The plating layer 19 has a first plating layer 19a formed on the first area W1 (contact area W4) and a second plating layer 19b formed on the second area W2. The first plating layer 19a and the second plating layer 19b are isolated from each other by the plating resist 40. The plating layer 19 is also formed on the plating resist 40 and is formed to project outward with increasing distance from the second principal surface 10b. Therefore, the first plating layer 19a is shaped to project toward the second plating layer 19b and the second plating layer 19b is shaped to project toward the first plating layer 19a. The plating layer 19 is formed such that a gap 42 is provided between the first plating layer 19a and the second plating layer 19b isolated by the plating resist 40.

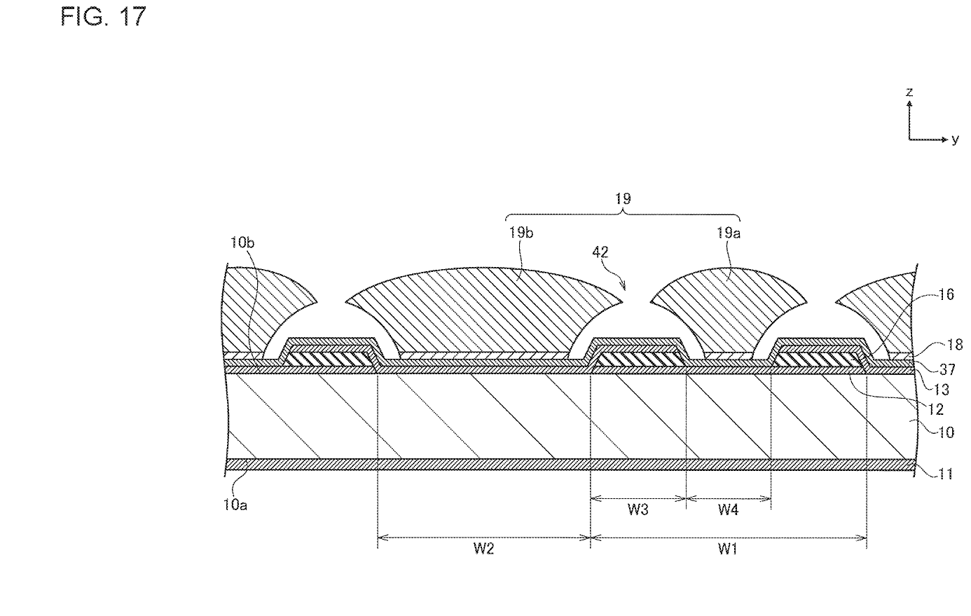

Subsequently, the plating resist 40 is removed as shown in FIG. 17. By removing the plating resist 40, a portion of the seed layer 38 exposed on the surface can be removed by etching. This ensures that a portion of the seed layer 38 sandwiched by the transparent conductive layer 37 and the plating layer 19 remains, thereby forming the seed layer 18. Thus, the plating layer 19 is formed by so-called “semi-additive method”.

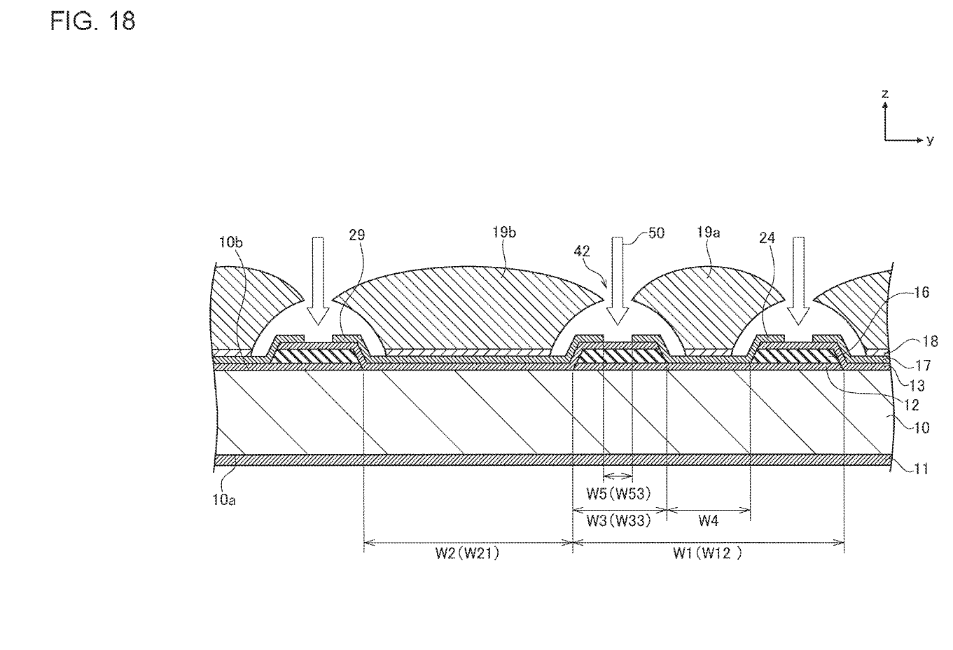

Subsequently, as shown in FIG. 18, the gap 42 between the first plating layer 19a and the second plating layer 19b is irradiated with laser 50 to remove a portion of the transparent conductive layer 37 and form the isolation area W5 (finger isolation area W53). In this way, the transparent conductive electrode 37 is separated into the first transparent conductive layer 24 and the second transparent conductive layer 29, thereby forming the transparent conductive layer 17.

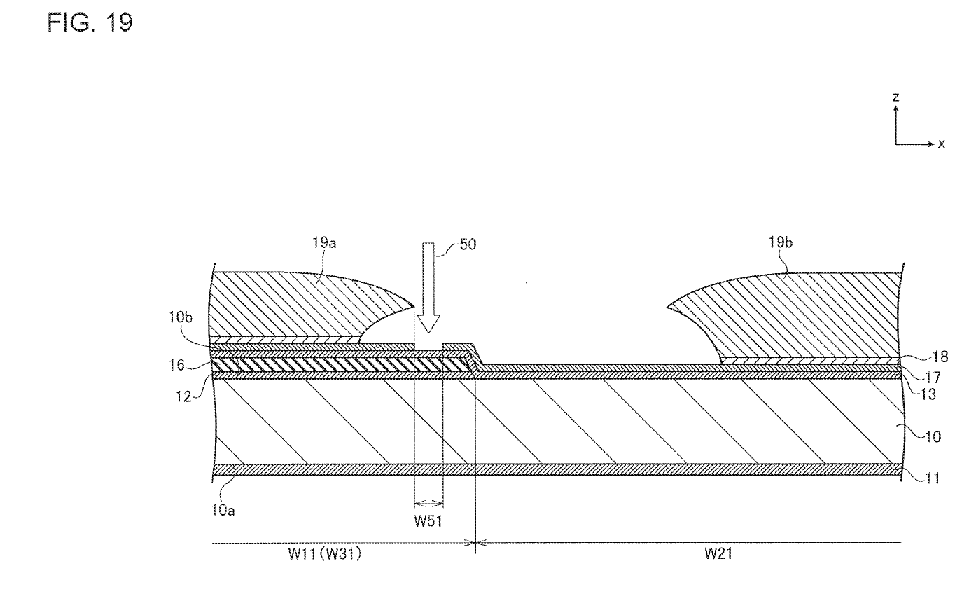

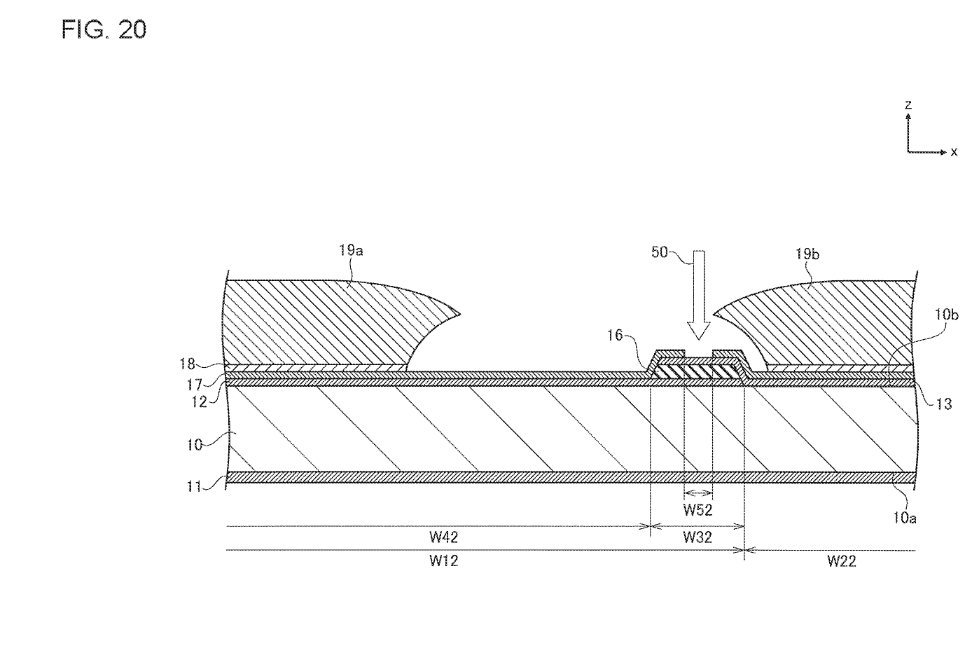

Further, as shown in FIG. 19, the laser 50 is projected along the first plating layer 19a provided on the first bus bar area W11 so as to remove a portion of the transparent conductive layer 37 and form the first bus bar area W51. Further, as shown in FIG. 20, the laser 50 is projected along the second plating layer 19b provided on the second bus bar area W22 so as to remove a portion of the transparent conductive layer 37 and form the second bus bar isolation area W52.

The solar cell 70 shown in FIGS. 1 to 7 is manufactured through the steps described above.

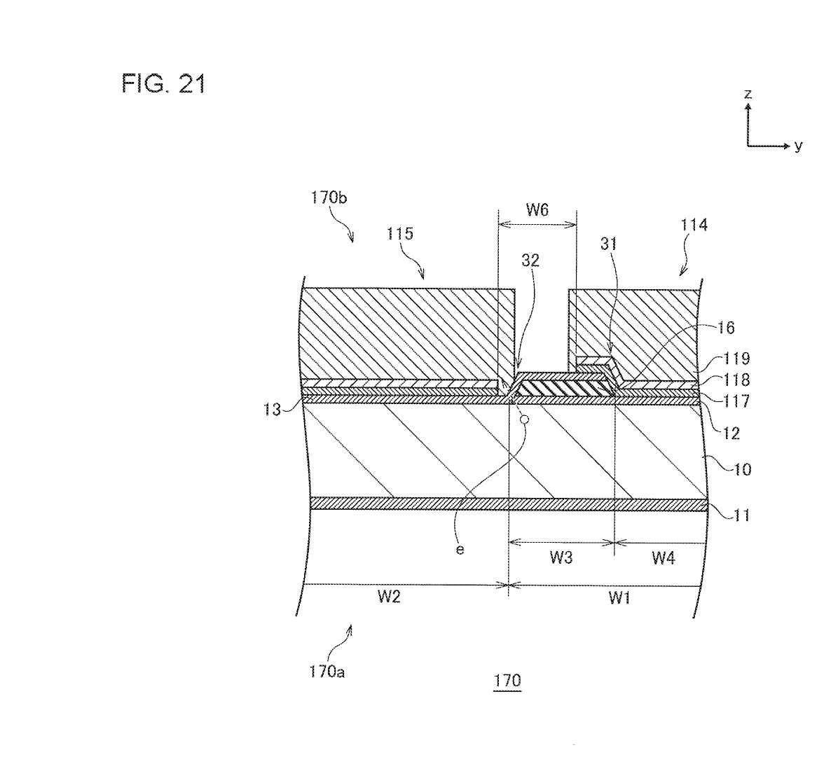

A description will now be given of the advantage provided by the solar cell 70 according to the embodiment with reference to a solar cell 170 according to a comparative example shown in FIG. 21.

FIG. 21 is a cross sectional view showing the structure of the solar cell 170 according to the comparative example and shows the structure corresponding to the cross section shown in FIG. 2. The solar cell 170 is a back surface junction type photovoltaic device having a structure similar to that of the solar cell 70 according to the embodiment described above. Meanwhile, the solar cell 170 differs from the embodiment in respect of the structure and manufacturing method of a transparent conductive layer 117 constituting a first electrode 114 and a second electrode 115, a seed layer 118, and a plating layer 119.

The solar cell 170 is built by forming, after the step shown in FIG. 11, an isolation area W6 by removing a portion of the transparent conductive layer 37 and the seed layer 38 positioned in the insulating area W3, and forming the plating layer 119 to grow on the isolated seed layer 118. The plating layer 119 grows isotropically from the seed layer 118 as a basis and so is formed on the first step 31 positioned at the boundary between the insulating area W3 and the contact are W4. Further, the plating layer 119 is formed after the isolation area W6 is formed and so is formed on and in direct contact with the semiconductor layer 13 exposed on the isolation area W6.

The isolation area W6 is not necessarily formed within the range of the insulating area W3 due to the variation in the manufacturing. As shown in FIG. 21, the isolation area W6 may be formed so as to be shifted from the insulating area W3. In order to improve the output profile of the solar cell 170, it is desired that the width of the first area and the second area positioned below the finger electrode extending in the x direction be small. For formation of the isolation area W6, high positional precision is called for. Therefore, the position of the isolation area W6 may be shifted as shown in the figure due to the variation in the manufacturing. If the isolation area W6 is formed so as to be shifted toward the second area W2, the second semiconductor layer 13 may be exposed at the second step 32 positioned between the second area W2 and the insulating area W3 so that the plating layer 119 may be in direct contact with the second semiconductor layer 13 on the second step 32.

The second step 32 includes a portion in which the first semiconductor layer 12 and the second semiconductor layer 13 are in direct contact so that a portion of electrons collected by the n-type first semiconductor layer 12 flow into the second electrode 115 via the second semiconductor layer 13 in direct contact. This results in electrons being recombined with holes collected by the p-type second semiconductor layer 13 and flowing into the second electrode 115 so that junction leak may be produced. In particular, the plating layer 119 has higher conductivity than the transparent conductive layer 117 so that the junction leak may grow due to direct contact of the plating layer 119 with the second semiconductor layer 13 in the second step 32.

Meanwhile, in the solar cell 70 according to the embodiment shown in FIG. 2, the isolation area W5 is provided after the plating layer 19 is formed so as to separate the transparent conductive layer 17. Therefore, the plating layer 19 is prevented from being in direct contact with the semiconductor layer 13 beneath the transparent conductive layer 17. This prevents the plating layer 19 from being in direct contact with the semiconductor layer 13 in the second step 32 to produce junction leak. In this way, the reliability of the solar cell 70 is improved.

According to the embodiment, the isolation area W5 in the transparent conductive layer 17 is formed by using the gap between the first metal electrode 21 and the second metal electrode 26 as a mask. Therefore, there is no need to provide a mask separately to form the isolation area W5. Since the position of the isolation area W5 is determined by the position of the gap between the first metal electrode 21 and the second metal electrode 26 in a self-aligned manner so that the position of forming the isolation area W5 is prevented from being shifted. In this way, the reliability of the solar cell 70 is improved.

In further accordance with the embodiment, the gap between the first metal electrode 21 and the second metal electrode 26 is used to form the isolation area W5 in the transparent conductive layer 17. Therefore, the portions of the transparent conductive layer 17 covered by the first overhanging portion 23 and the second overhanging portion 28 are prevented from being removed. This ensures that the transparent conductive layer 17 is provided between the first semiconductor layer 12 and the plating layer 19 and between the second semiconductor layer 19 and the plating layer 19 so that the plating layer 19 is prevented from being in direct contact with the semiconductor layer. In this way, the reliability of the solar cell 70 is improved.

In still further accordance with the embodiment, the plating layer 19 is shaped to project toward the insulating area W3 with increasing distance from the principal surface. Therefore, the plating layer 19 is prevented from being in direct contact with the transparent conductive layer 17 in the first step 31 or the second step 32. Generally, the semiconductor substrate 10 and the plating layer 19 differ in the coefficient of thermal expansion so that a stress is produced due to the difference in the amount of expansion and contraction caused by the temperature change. Therefore, if the plating layer having a large film thickness is provided on the first step 31 or the second step 32, the stress produced due to the temperature change may be concentrated in the first step 31 or the second step 32 and may cause damage to the step. According to this embodiment, the plating layer 19 is formed above the first step 31 and the second step 32 so as not to be in directed contact therewith. Therefore, concentration of a stress in the first step 31 or the second step 32 is prevented. In this way, the reliability of the solar cell 70 is improved.

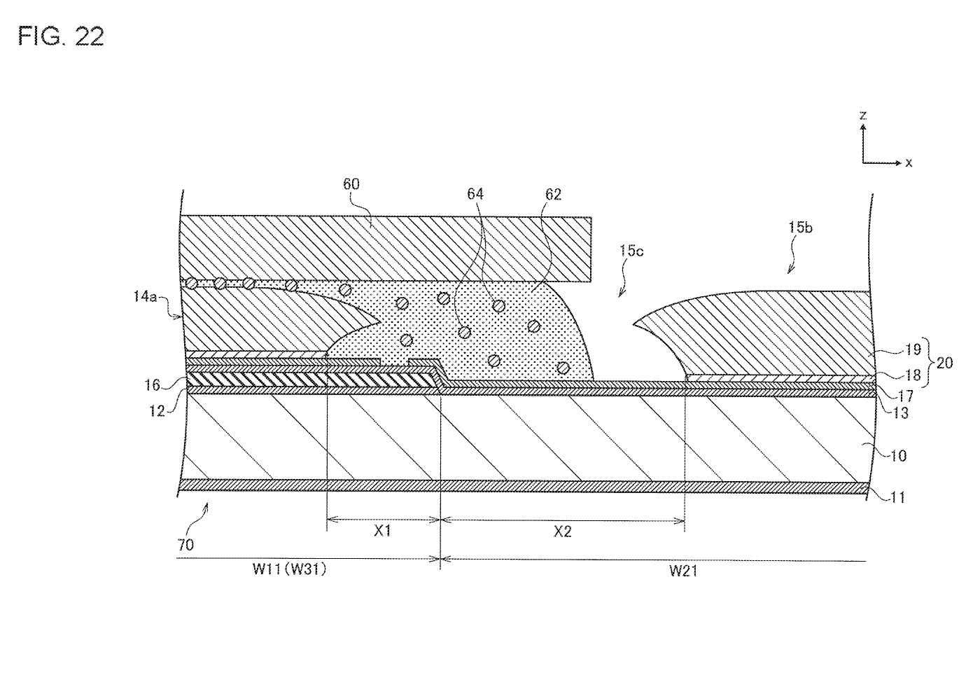

In yet further accordance with the embodiment, the first finger end portion 14c and the second finger end portion 15c not having a metal electrode are provided. Therefore, the first electrode 14 and the second electrode 15 in the same cell are prevented from being short-circuited by a connection member connecting between each of a plurality of solar cells 70. The advantage will be explained with reference to FIG. 22.

FIG. 22 is a cross sectional view showing the structure of the solar cell 70 on which a connection member is attached. The solar cell 70 is modularized by connecting a plurality of solar cells 70 by a connection member 60. The connection member 60 connects the first bus bar electrode 14a of the first solar cell 70 and the second bus bar electrode of the second solar cell. The figure shows the connection member 60 attached to the first bus bar electrode 14a of the first solar cell 70 and the second solar cell is omitted from the illustration.

The connection member 60 is provided to extend across the first bus bar electrode 14a and the second finger end portion 15c and is attached to the solar cell 70 by an adhesive 62. The adhesive 62 is a thermosetting resin in which conductive particles 64 are mixed. The connection member 60 and the first bus bar electrode 14a are electrically connected via the conductive particles 64 and the connection member 60 and the second finger end portion 15c are electrically insulated by the adhesive 62.

According to the embodiment, the second finger end portion 15c is provided so that the first bus bar electrode 14a and the second finger electrode 15b are prevented from being short-circuited as a result of the connection member 60 being in contact with the second finger electrode 15b. For high power generation efficiency of the solar cell 70, it is desired that the first bus bar insulating area W31, a void area, be as small as possible. It is therefore desired that the width of the first bus bar electrode 14a provided on the first bus bar insulating area W31 in the x direction be also small by some measure. Meanwhile, if the width of the first bus bar electrode 14a in the x direction is small, high precision is required to attach the electrode to the connection member 60. Depending on the variation in the manufacturing, the end of the connection member 60 may approximate the second finger electrode 15b. In attaching the connection member 60 to the first bus bar electrode 14a by applying a pressure, the adhesive 62 flows toward the second finger area W21. In this process, the height of the adhesive 62 may exceed the height (z direction) of the first bus bar electrode 14a and the second finger electrode 15b, if a sufficient space is not available between the first bus bar electrode 14a and the second finger electrode 15b. This may result in reduction of the adherence between the first bus bar electrode 14a and the connection member 60. According to this embodiment, a certain room is provided between the connection member 60 attached to the first bus bar electrode 14a and the second finger electrode 15b by providing the second finger end portion 15c. This ensures that the connection member 60 is suitably connected to the first bus bar electrode 14a.

One mode of the embodiment relates to a method of manufacturing a solar cell 70. The method includes: forming a first semiconductor layer 12 of a first conductivity type in a first area W1 on a principal surface (second principal surface 10b) of a semiconductor substrate 10 having the first area W1 and a second area W2 adjacent to each other; forming an insulating layer 16 on the first semiconductor layer 12 in an insulating area W3 that is part of the first area W1 and adjacent to the second area W2; forming a second semiconductor layer 13 of a second conductivity type to extend across the principal surface (second principal surface 10b) in the second area W2 and the insulating layer 16 in the insulating area W3; forming a transparent conductive layer 17 on the first semiconductor layer 12 and the second semiconductor layer 13; forming a seed layer 18 on the transparent conductive layer 17; forming a plating layer 19 to grow on the seed layer 18 and on a plating resist 40 provided on the seed layer 18 in the insulating area W3; and removing the plating resist 40 and removing a portion of the transparent conductive layer 17 and the seed layer 18. The forming the plating layer 19 includes forming a first plating layer 19a on the first area W1 and forming a second plating layer 19b on the second area W2, the forming the second plating layer 19b includes forming the second plating layer 19b to project to approach the first plating layer 19a with increasing distance from the principal surface (second principal surface 10b) and such that a gap 42 is provided between the second plating layer 19b and the first plating layer 19a, and the removing a portion of the transparent conductive layer 17 and the seed layer 18 includes irradiating a portion of the transparent conductive layer 17 with laser or dry etching the transparent conductive layer 17, by using the gap 42 as a mask.

The removing a portion of the transparent conductive layer 17 and the seed layer 18 may include wet etching the seed layer 18.

The forming the plating layer 19 may include providing a plating resist 40 to cover a portion of the second area W2 adjacent to the insulating area W3.

The first area W1 may include a plurality of first finger areas W12 extending in an x direction and a first bus bar area W1 connected to one end of the plurality of first finger areas W12 and extending in a y direction, the second area W2 may include a plurality of second finger areas W21 extending in the x direction and a second bus bar area W22 connected to one end of the plurality of second finger areas W21 and extending in the y direction, and the first area W1 and the second area W2 may be provided such that the plurality of first finger areas W12 and the plurality of second finger areas W21 are inserted into each other, and the forming the plating layer 19 may include providing the plating resist 40 such that the plating resist 40 extends in the x direction across a boundary between the first bus bar area W11 and the second finger area W21, and a length X2 of the plating layer 19 from the boundary toward the second finger area W21 is larger than a length X1 of the plating layer 19 from the boundary toward the first bus bar area W11.

The forming the first plating layer 19 may include forming a first bus bar electrode 14a extending in the y direction in the first bus bar area W11, and the removing a portion of the transparent conductive layer 17 and the seed layer 18 may include removing a portion of the transparent conductive layer 17 by irradiating the transparent conductive layer 17 with laser in the y direction along the first bus bar electrode 14a.

Another mode relates to a solar cell 70. The solar cell 70 includes a semiconductor substrate 10 having a principal surface (second principal surface 10b) in which a first area W1 and a second area W2 adjacent to each other are provided; a first semiconductor layer 12 of a first conductivity type provided in the first area W1 on the principal surface (second principal surface 10b); an insulating layer 16 provided on the first semiconductor layer 12 in an insulating area W3 that is part of the first area W1 and adjacent to the second area W2; a second semiconductor layer 13 of a second conductivity type provided to extend across the principal surface (second principal surface 10b) in the second area W2 and the insulating layer 16 in the insulating area W3; a transparent conductive layer 17 provided on the first semiconductor layer 12 and the second semiconductor layer 13; a first metal electrode 21 provided on the transparent conductive layer 17 in the first area W1; and a second metal electrode 26 provided on the transparent conductive layer 17 in the second area W2, wherein the second metal electrode 26 is formed to have an overhanging portion (second overhanging portion 28) projecting to approach the first metal electrode 21 with increasing distance from the principal surface (second principal surface 10b) and such that a gap from the first metal electrode 21 is positioned in the insulating area W3, and the transparent conductive layer 17 is provided to avoid an isolation area W5 in the insulating area W3 aligned with the gap.

The overhanging portion (second overhanging portion 28) may project from the second area W2 toward the insulating area W3 so as to extend across a boundary between the second area W2 and the insulating area W3.

The first metal electrode 21 may include a plurality of first finger electrodes 14b extending in an x direction and a first bus bar electrode 14a connected to one end of the plurality of first finger electrodes 14b and extending in a y direction, the second meal electrode 26 may include a plurality of second finger electrodes 15b extending in the x direction and a second bus bar electrode 15a connected to one end of the plurality of second finger electrodes 15b and extending in the y direction, the first metal electrode 21 and the second metal electrode 26 may be provided such that the plurality of first finger electrodes 14b and the plurality of second finger electrodes 15b are inserted into each other, the transparent conductive layer 17 may be provided to avoid a plurality of bus bar isolation areas (first bus bar isolation areas W51) positioned between the first bus bar electrode 14a and the plurality of second finger electrodes 15b, and the plurality of bus bar isolation areas (first bus bar isolation areas W51) may be provided closer to the first bus bar electrode 14a than the plurality of second finger electrodes 15b.

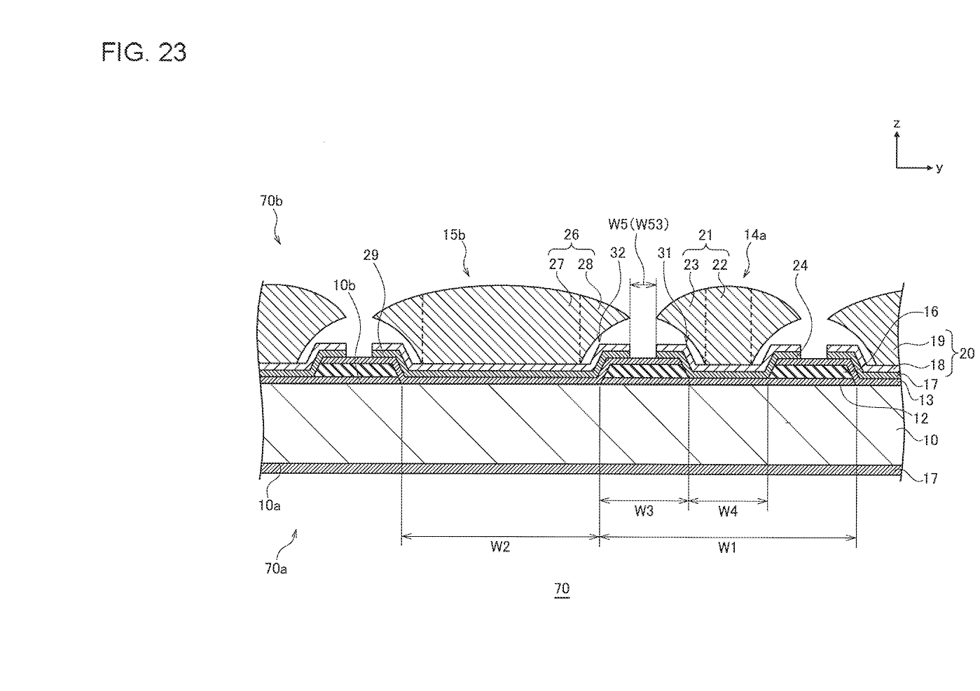

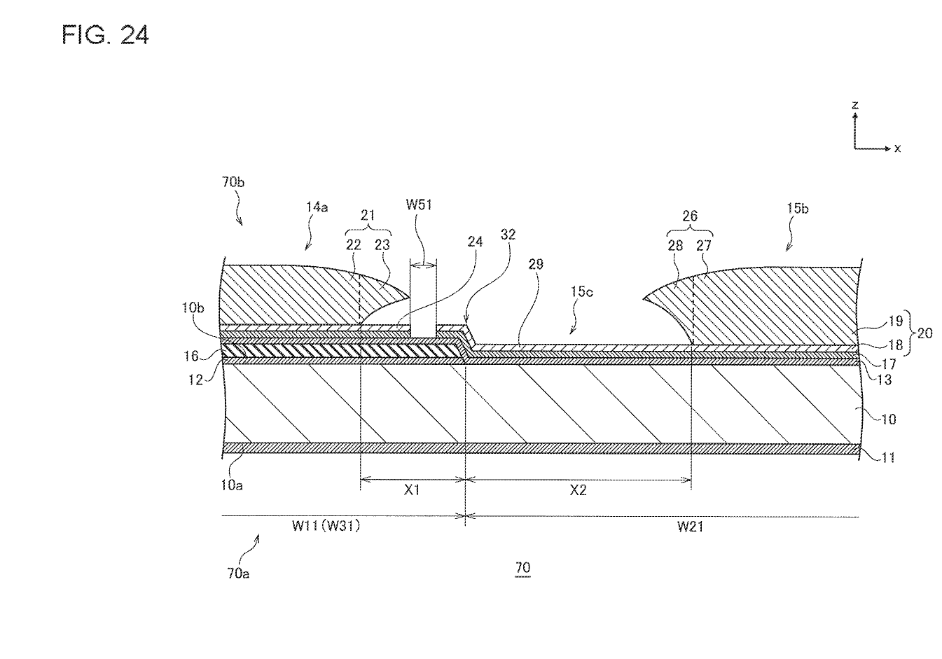

FIGS. 23 and 24 are cross sectional views showing the structure of the solar cell 70 according to a variation. FIG. 23 shows a cross section corresponding to FIG. 2 and FIG. 24 shows a cross section corresponding to FIG. 6. The variation differs from the embodiment described above in that the seed layer 18 is provided to avoid the isolation area W5 and cover the entirety of the transparent conductive layer 17. The solar cell 70 according to the variation is formed not by removing the seed layer 38 in the step shown in FIG. 17 of removing the plating resist 40 and removing a portion of the seed layer 38 and the transparent conductive layer 37 in the step of forming the isolation area W5 shown in FIGS. 18 to 20.

In this variation, the same advantage as described above of the embodiment is available. By allowing the seed layer 18 to remain in the second finger end portion 15c as shown in FIG. 24, the efficiency of collecting power in the second finger end portion 15c is increased. Similarly, by allowing the seed layer 18 to remain in the first finger end portion 14c, the efficiency of collecting power in the first finger end portion 14c is increased.

The step of removing a portion of the transparent conductive layer 17 and the seed layer 18 in the method of manufacturing the solar cell 70 described above may include dry etching a portion of the seed layer 18, using the gap 42 as a mask.

The embodiments of the present invention are not limited to those described above and appropriate combinations or replacements of the features of the embodiments are also encompassed by the present invention.

In the embodiment described above, the plating resist 40 is described as being provided to extend across the insulating area W3 and a portion of the second area W2 and the contact area W4 adjacent to the plating resist 40. In a further variation, the plating resist may be provided only in the range of the insulating area W3 or provided to extend over a portion of only one of the second area W2 and the contact area W4 adjacent to the plating resist 40. In this case, at least one of the first base portion and the second base portion of the plating layer may be provided in the insulating area W3.

In the embodiment and the variation described above, a portion of the transparent conductive layer 37 positioned in the isolation area W5 and a portion of the seed layer 38 are removed by laser irradiation. In a still further variation, a portion of the transparent conductive layer 37 and the seed layer 38 may be removed by using an etching gas. In other words, a portion of the transparent conductive layer 37 and the seed layer 38 is removed by laser irradiation or a dry etching method using an etching gas.

It should be understood that the invention is not limited to the above-described embodiments and modifications, but may be further modified into various forms on the basis of the spirit of the invention. Additionally, those modifications are included in the scope of the invention.

1. A method of manufacturing a solar cell, the method comprising:
forming a first semiconductor layer of a first conductivity type over a substrate;
forming an insulating pattern on the first semiconductor layer of the first conductivity type;
forming a second semiconductor layer of a second conductivity type over a portion of the substrate, at which the first semiconductor layer is not disposed, and over the insulating pattern;
forming a transparent conductive layer over the first semiconductor layer and the second semiconductor layer;
providing a resist pattern over a portion for insulation of the transparent conductive layer, the insulating pattern being disposed under the portion for isolation;
forming a conductive layer over the transparent layer except to the portion for isolation covered by the resist pattern;
after the conductive layer is formed, removing the resist pattern; and
forming a separation area by removing a part of the portion for isolation of the transparent conductive layer, wherein:
the forming the conductive layer includes forming a first plating layer above the first semiconductor layer and forming a second plating layer above the second semiconductor layer, by using an electroplating method;
each of the first plating layer and the second plating layer has a lower portion in contact with the transparent conductive layer and an upper portion hanging over the portion for isolation, a width of the lower portion is smaller than a width of the upper portion and a gap is provided between the second plating layer and the first plating layer; and
the forming the isolation area includes irradiating the transparent conductive layer with laser through the gap or dry etching the transparent conductive layer through the gap.

2. The method of manufacturing a solar cell according to claim 1, the method further comprising forming a seed layer on the transparent layer, wherein
the forming the isolation area includes wet etching a part of the seed layer.

3. The method of manufacturing a solar cell according to claim 1, wherein
the forming the isolation area includes dry etching a part of the seed layer, using the first plating layer and the second plating layer as a mask.

4. The method of manufacturing a solar cell according to claim 1, wherein
the forming the plating layer includes providing a plating resist to cover a portion of the second area adjacent to the insulating area.

5. The method of manufacturing a solar cell according to claim 1, wherein
the first conductivity layer includes a first finger area extending in an x direction and a first bus bar area connected to one end of the first finger areas and extending in a y direction,
the second conductivity layer includes a second finger area extending in the x direction and a second bus bar area connected to one end of the second finger area and extending in the y direction, and
the first conductivity layer and the second conductivity layer are provided such that the first finger area and the second finger area are next to each other in x direction, and
the forming the plating layer includes providing the plating resist such that the plating resist extends in the x direction across a boundary between the first bus bar area and the second finger area, and a length of the plating resist from the boundary toward the second finger area is larger than a length of the plating resist from the boundary toward the first bus bar area.

6. The method of manufacturing a solar cell according to claim 5, wherein
the forming the first plating layer includes forming a first bus bar electrode extending in the y direction in the first bus bar area, and
the forming the isolating area includes removing a part of the transparent conductive layer by irradiating the transparent conductive layer with laser in the y direction along the first bus bar electrode.

7. A solar cell comprising:
a first semiconductor layer of a first conductivity type;
an insulating layer provided on the first semiconductor layer;
a second semiconductor layer of a second conductivity type provided to extend across the insulating layer on the first semiconductor layer;
a transparent conductive layer provided over the first semiconductor layer and the second semiconductor layer;
a first metal electrode provided above the transparent conductive layer corresponds to an area that the first conductivity layer is provided; and
a second metal electrode provided above the transparent conductive layer corresponds to an area that the second conductivity layer is provided, wherein
the second metal electrode is formed to have an overhanging portion projecting to approach the first metal electrode with increasing distance from the principal surface and such that a gap from the first metal electrode is positioned in the insulating area, and
the transparent conductive layer is provided to avoid an isolation area over the insulating layer aligned with the gap.

8. The solar cell according to claim 7, wherein
the overhanging portion projects so as to extend across a boundary between the second area and the insulating area.

9. The solar cell according to claim 7, wherein
the first metal electrode includes a first finger electrode extending in an x direction and a first bus bar electrode connected to one end of the first finger electrodes and extending in a y direction,
the second metal electrode includes a second finger electrode extending in the x direction and a second bus bar electrode connected to one end of the second finger electrode and extending in the y direction,
the first conductivity layer and the second conductivity layer are provided such that the first finger area and the second finger area are next to each other in x direction, and
the transparent conductive layer is provided to avoid a bus bar isolation area positioned between the first bus bar electrode and the second finger electrodes, and
the bus bar isolation area is provided closer to the first bus bar electrode than the second finger electrodes.

10. The method for manufacturing a solar cell according to claim 1, wherein
a width of the gap and a width of the isolation area are equal.

11. The method for manufacturing a solar cell according to claim 1, wherein
the plating layer made from the metal selected from the group consisted of Cu, Sn, Au Ag, Ni and Ti.

12. The method for manufacturing a solar cell according to claim 1, wherein
the plating resist provided so as to form a hemisphere like shape.

13. The method for manufacturing a solar cell according to claim 1, wherein
an edge of the insulating area between the second finger areas and the first bas bar area is aligned with at least one of an edge of the first plating layer or an edge of the second plating layer.

14. The method for manufacturing a solar cell according to claim 1, wherein
a width of the finger portions of the second plating layer is larger than a width of the finger portions of the first plating layer.

15. The method for manufacturing a solar cell according to claim 14, wherein
the first conductivity is n-type and the second conductivity is p-type.

16. The solar cell according to claim 7, wherein
the first metal layer and the second metal layer made from the material selected from the group consisted of Cu, Sn, Au Ag, Ni and Ti.

17. The solar cell according to claim 7, wherein
a width of the gap and a width of the isolation area is equal in side view.

18. The solar cell according to claim 9, wherein
an edge of the insulating area between the second finger areas and the first bas bar area is aligned with at least one of an edge of the first metal electrodes or an edge of the second metal electrodes.

19. The solar cell according to claim 7, wherein
a width of the finger portions of the second metal electrode is larger than a width of the finger portions of the first metal electrode.

20. The solar cell according to claim 19, wherein
the first conductivity is n-type and the second conductivity is p-type.
